(19) United States
(12) Patent Application Publication
(10) Pub. No.: US 2011/0156163 A1
(43) Pub. Date: Jun. 30, 2011

(54) Structure of electrode pick up in LOCOS

(76) Inventors: Tzuyin CHIU, Shanghai (CN); TungYuan Chu, Shanghai (CN); YungChieh Fan, Shanghai (CN); Wensheng Qian, Shanghai (CN); Jiong Xu, Shanghai (CN); Fan Chen, Shanghai (CN); Haifang Zhang, Shanghai (CN)

(21) Appl. No.: 12/979,802

(22) Filed: Dec. 28, 2010

(30) Foreign Application Priority Data
Dec. 31, 2009 (CN) 200910202068.7

(51) Int. Cl. H01L 23/535; H01L 23/48

(52) U.S. Cl. 257/383; 257/508; 257/E23.011; 257/E23.168

(57) ABSTRACT

This invention disclosed a kind of electrode picking up structure in LOCOS isolation process. The active region is isolated by local oxide of silicon (LOCOS). A pseudo buried layer under the bottom of LOCOS is formed. The pseudo-buried layer extends into active region and connects to doping region one which needs to be picked up by an electrode. This is achieved by deep trench contacts which etch through LOCOS and get in touch with pseudo buried layer. This invention can reduce the device size, pick up electrode resistance, collector parasitic capacitance, and increase device cut off frequency.

The current invention claims a foreign priority to application China 200910202068.7 filed on Dec. 31, 2009.

### FIELD OF THE INVENTION

This invention relates to a kind of semiconductor integrated circuit device. More particularly it relates to one type of electrode pick up structure in LOCOS isolation and its fabrication method.

### BACKGROUND OF THE INVENTION

Shown in FIG. 1A is a conventional bipolar transistor structural drawing, active region is isolated by local oxidation in silicon (LOCOS) 104. The transistor includes a collector region 102, a base region 105, and an emitter region 107. The collector region shown is consisted of an epitaxy layer, which connects to a high doped buried layer 101 at bottom. The collector region 102 is connected to the buried layer 101 and a high energy implanted active region 103 which is separated by a LOCOS, the collector is picked up by a contact on the high energy implanted region 103. The base is formed on top of collector region 102, including an intrinsic base 105 and an extrinsic base 106, the intrinsic base 105 is in conjunction with the collector region 102, and is picked up by a metal contact to extrinsic base region 106. The emitter region 107 is formed on top of base region 105, and is picked up directly as an emitter by metal contact, dielectric layer 108 is the isolation material between emitter 107 and intrinsic base 105. As the collector is picked up through high energy implanted region 103, via buried layer 101, to the collector active region 102 which is separated by LOCOS 104 to 103, the total area is large, which induced high collector parasitic capacitance.

### SUMMARY OF THE INVENTION

Present invention gives a technical solution of an electrode pick up structure in LOCOS isolation process. It can reduce overall device size, reduce collector electrode pick up resistance and collector parasitic capacitance, and increase device cut off frequency.

To resolve above mentioned technical issues, the electrode picking up structure in LOCOS process by this invention, active region is isolated by LOCOS. There is a first conductive type pseudo buried layer formed beneath the LOCOS. The pseudo buried layer extends to first conductive type doped active region one which needs to be picked up. A deep trench contact is made through LOCOS and connects to the pseudo buried layer and pick up the electrode of doped region one.

The pseudo-buried layer mentioned above is an ion implant layer of the first conduction type, it can be either N type or P type, whose doping concentration should satisfy the condition that the deep trench contact of the doped area to metal is of ohmic contact.

The deep trench contact is a deep trench hole filled the deep trench with titanium /titanium nitride (Ti/TiN) barrier metal and tungsten.

In present invention, the pick up electrode to doped region one in active is formed by the deep trench contact through LOCOS and connected to the pseudo buried layer. Compared to existing way of electrode pick up approach, such as existing bipolar transistor collector pick up, in which collector region connects to the buried layer and bypasses LOCOS, then link with high energy ion implant layer and finally to contact, present invented electrode pick up can dramatically reduce device size. At the same time the deep trench contact hole is close to device active region, device collector connection path resistance and parasitic capacitance can be decreased, and device cut off frequency can be increased.

### BRIEF DESCRIPTION OF THE DRAWINGS

The foregoing and the object, features, and advantages of the invention will be apparent from the following detailed description of the invention, as illustrated in the accompanying drawings, in which:

FIG. 1 is the existing bipolar transistor structure drawing;

FIG. 2 is this invention's first implementation example structure drawing;

FIG. 3A-FIG. 3F is this invention's first implementation example manufacturing process flow structure drawing;

FIG. 4 is this invention's second implementation example structure drawing.

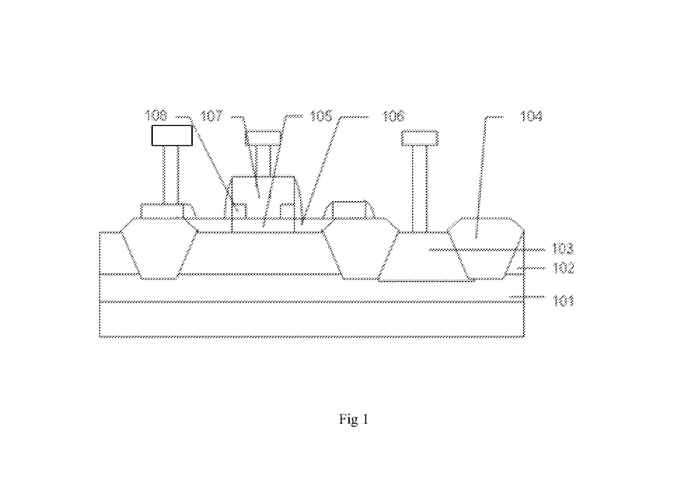

### EXPLANATION OF LABELS IN THE ATTACHED FIGURE

| | |
|---|---|
| 101: heavily doped buried layer | 102: collector region |
| 103: high energy implanted region | 104: local field oxide region |
| 105: intrinsic base | 106: extrinsic base |
| 107: emitter region | 108: isolation region |
| 200: pad oxide layer | 201: local field oxide region |
| 202: silicon nitride | 203: pseudo-buried layer |
| 204: deep trench contact | 205: intrinsic base |
| 206: extrinsic base | 207: emitter region |
| 208: emitter region insulator layer | 209: ILD |
| 210: ion implanted layer | |
| 401: local field oxidation layer | 402: N well or P well |
| 403: pseudo-buried layer | 404: deep trench contact hole |

### DETAILED DESCRIPTION OF THE INVENTION

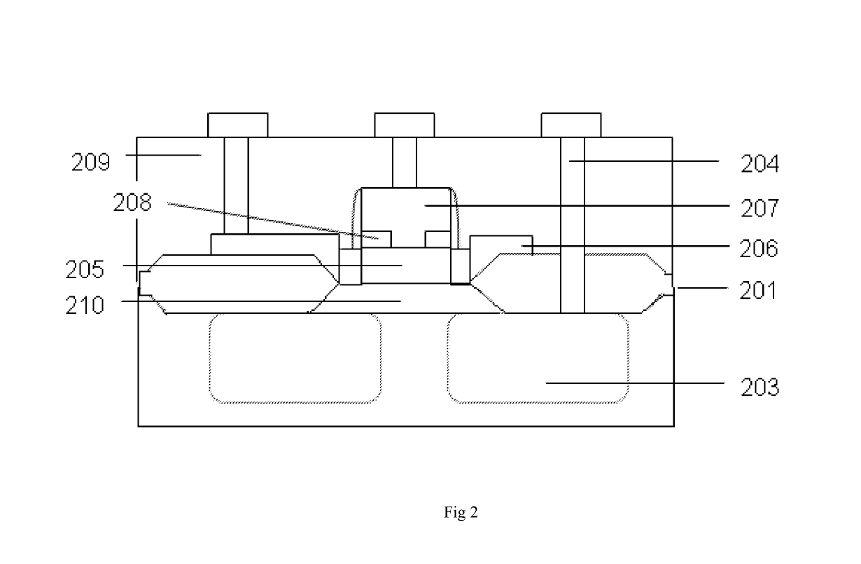

As shown in FIG. 2, it is structural illustration of the first implementation of present invention, it is a bipolar transistor. Its active area is isolated by LOCOS 201, the bipolar transistor includes a collector region 210, a base region and an emitter region 207. The base region is formed by a second conduction type epitaxy layer which is above the collector region 201, the base region includes an intrinsic base 205 and an extrinsic base 206, the intrinsic base 205 is in conjunction with collector region 210, the base is picked up by a metal contact hole to extrinsic base 206. The emitter 207 is formed by a first conduction type polysilicon on top of base. The emitter is picked up by a metal contact formed directly on top of polysilicon. The collector 210 is the above referred doped region one, it consists of first conduction type ion implantation layer, and is connected to first conduction type pseudo buried layer 203 at bottom of LOCOS, the pseudo buried layer is formed in substrate by ion implantation, during the process of LOCOS grow, the ion impurity diffuses vertically to LOCOS, laterally to active region and links with collector ion implanted layer 210, collector pick up is made by a deep trench contact 204 which penetrates LOCOS 201 to pseudo buried layer 203, the deep contact 204 which picks up the collector should penetrate both inter layer dielectric (ILD) 209 and LOCOS, and finally form electric contact by filling the deep trench hole with conduct layer Ti/TiN and metal layer tungsten.

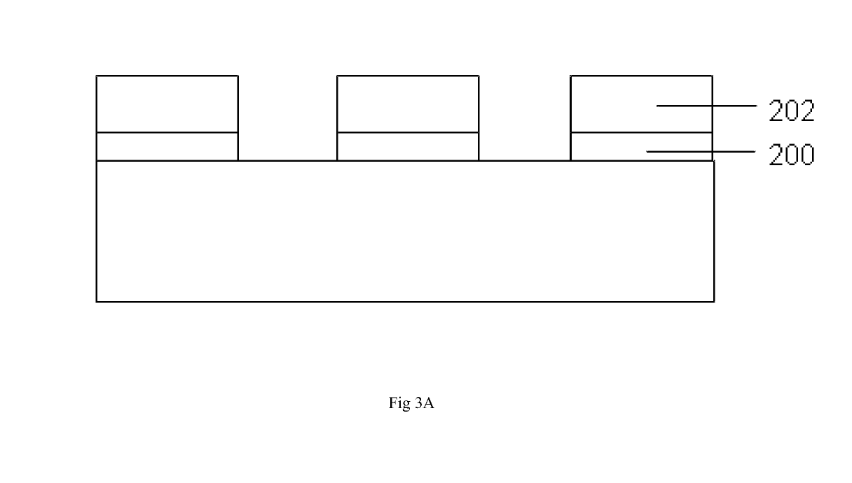

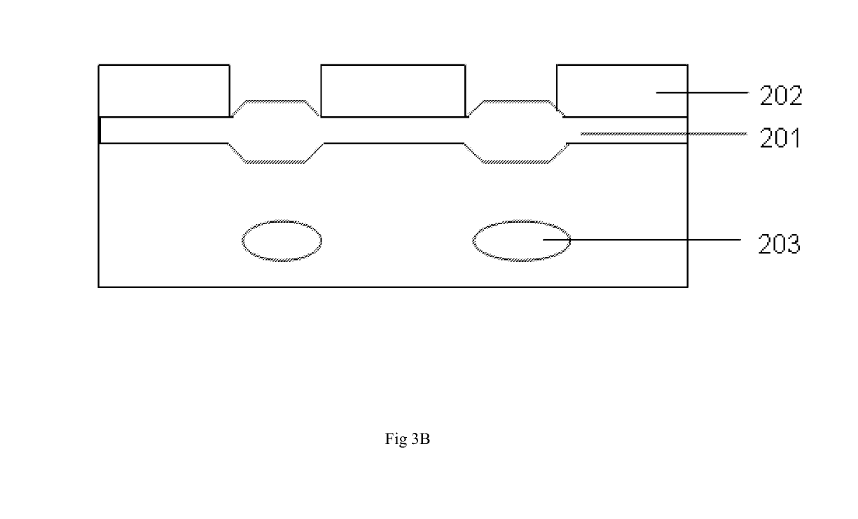

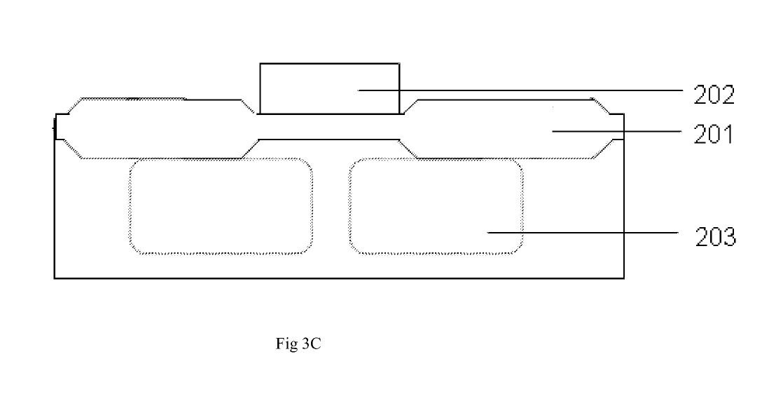

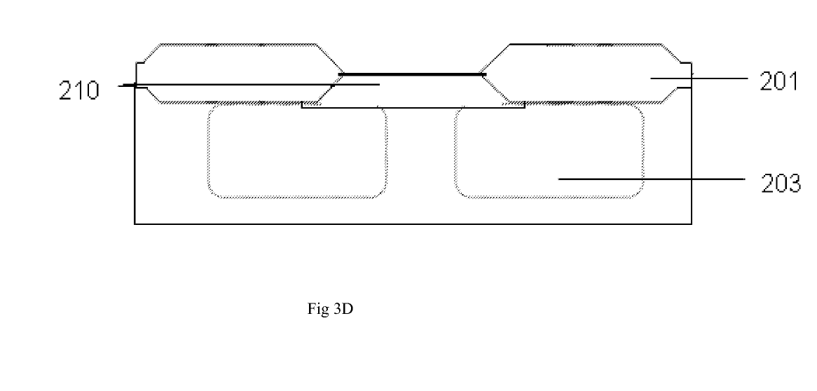

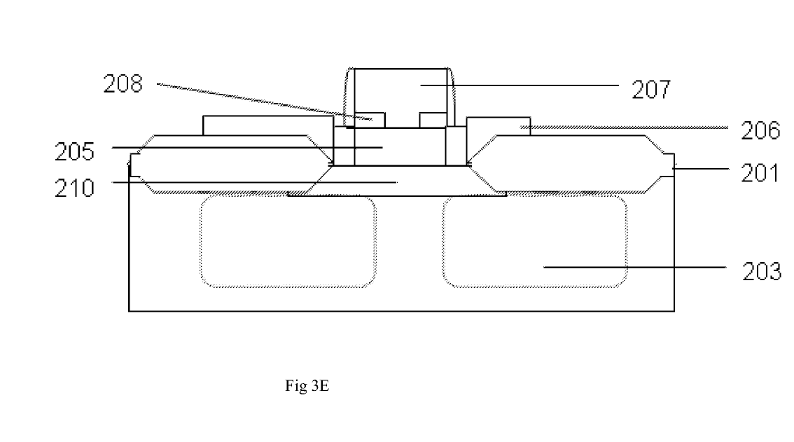

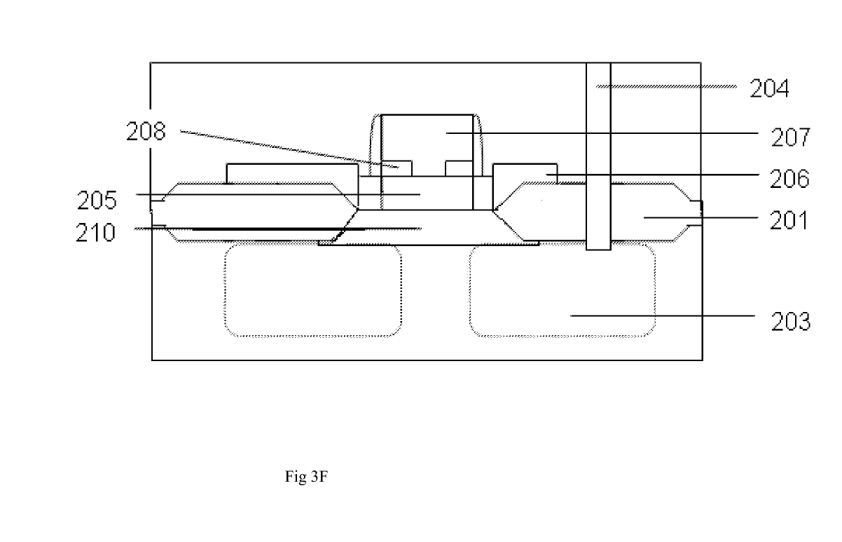

FIG. 3A-FIG. 3F show the manufacturing process flow structural view of present invented electrode pick up structure in LOCOS isolation process of a bipolar transistor. Following process steps are included:
1. Refer to FIG. 3A, forming the active region: grow pad oxide 200 thermally and deposit silicon nitride 202 as hard mask, first photo layer is performed and first active region is defined. The purpose of the first active region is to define pseudo buried layer implant region. Silicon nitride and pad oxide is etched away from non active region defined by resist mask, the size of open area is determined by pseudo buried layer implantation area.
2. Refer to FIG. 3B, the silicon nitride 202 is used as active area stop layer for ion implantation, pseudo buried layer 203 is formed by N type or P type ion implantation. The implant dosage is 1E14˜1E16 cm−2, and the energy is less than 30 keV. First field oxidation is performed to form LOCOS 201 for isolation.
3. Refer to FIG. 3C, second litho process is performed after first LOCOS 201 formation. The final active region is defined then. Silicon nitride on final active region is protected by photo resist, while the silicon nitride in other area is etched away by dry etch. A second field oxidation is performed and final isolation region is formed. During field oxidation, the ion impurity inside pseudo buried layer 203 diffuse upward to LOCOS 201 and diffuse laterally to active region.
4. Refer to FIG. 3D, the silicon nitride 202 and pad oxide are removed, and collector 210 is formed by ion implantation.
5. Refer to FIG. 3E, intrinsic base region 205, emitter 207, extrinsic base 206, and isolation layer 208 between base and collector are all formed.
6. Refer to FIG. 3F, inter layer dielectric (ILD) 209 is formed. Deep contact etch is performed to LOCOS 201 on top of pseudo buried layer 203. Dry etch is adopted. The deep contact penetrates ILD 209 and LOCOS 201, and finally reach pseudo buried layer 203. The deep contact hole is then filled with barrier metal layer Ti/TiN and metal layer tungsten to form deep contact pick up 204.
7. Refer to FIG. 2, metallic contact is formed on above mentioned base and emitter. The first type device of present invention is finished.

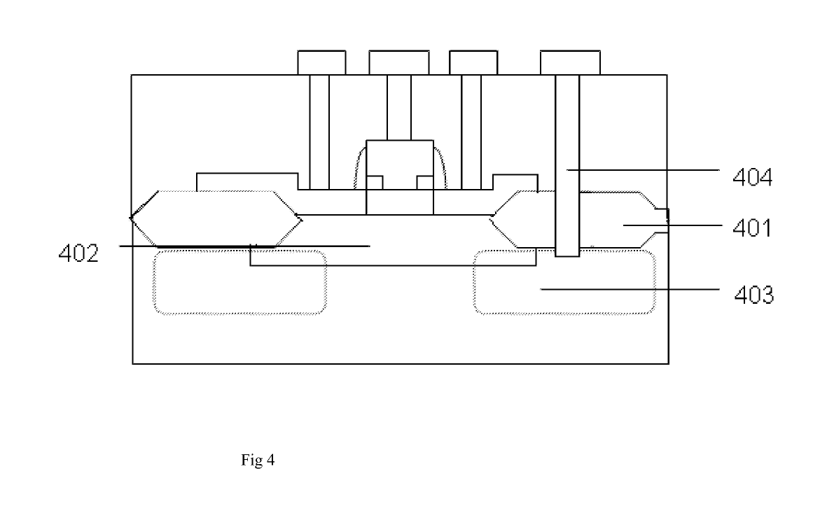

As shown in FIG. 4, it is structural illustration of second implementation of present invention. It is a substrate pick up structure of a MOS transistor in field oxide isolation (LOCOS) process. The MOS transistor is formed in active region which is isolated by LOCOS 401. Source, drain and gate are picked up directly by metallic contact. Substrate is picked up by deep trench contact 404 through LOCOS 401 and connecting to pseudo-buried layer 403. The pseudo-buried layer connects to N well or P well 402. Thus N well or P well is connected. N well or P well 402 corresponds to above stated doping region one. N well corresponds to PMOS transistor while P well corresponds to NMOS transistor.

Above invention has been detailed by concrete implementation examples. However the invention is by no means restricted by above descriptions. Thus, technical staffs in this area can make various deformation and improvement under this principle. These deformation and improvement should be considered as within the scope of this invention.

1. An electrode pick up structure in local oxide of silicon (LOCOS) process, comprises: an active region isolated by LOCOS; a pseudo buried layer of the first conduction type under the bottom of LOCOS; a deep trench contact connect inside the LOCOS;
wherein the pseudo buried layer extends to the active region and connects to the doping region one of the first conduction type;
the deep trench contact connects to the pseudo buried layer, and links to the electrode of the doping region one.

2. The electrode pick up structure in a LOCOS process of claim 1 comprises: the pseudo buried layer is an ion implant layer of the first conduction type; the pseudo buried layer is either N type or P type, a doping concentration of the pseudo buried layer satisfies the formation of ohmic contact with the metal that fills the deep trench contact.

3. The electrode pick up structure in a LOCOS process of claim 1 comprises: the deep trench contact is a deep trench hole filled with Titanium /titanium nitride (Ti/TiN) barrier metal and tungsten (W).

4. The electrode pick up structure in a LOCOS process of claim 1 comprises: the pseudo buried layer is consisted of a diffusion region of ion implantation area beneath the LOCOS after subsequent thermal annealing process, the thermal diffusion region of pseudo buried layer extend upward to the bottom of LOCOS and in contact with LOCOS, the thermal diffusion region of pseudo buried layer also extend laterally into active region and links with doping region one.

5. The electrode pick up structure in a LOCOS process of claim 1 comprises: the doping region one is an ion implanted layer.

6. The electrode pick up structure in a LOCOS process of claim 1 comprises: the electrode pick up structure is an output structure of collector of a bipolar structure; the doping region one is a collector region of the bipolar transistor.

7. The electrode pick up structure in a STI process of claim 1 comprises: the electrode pick up structure is an output structure of a substrate of a MOS transistor;
the doping region one is the substrate of a MOS transistor that forms a channel between source and drain of the MOS transistor; wherein the substrate can be either an n-well or a p-well,
the n-well corresponds to a PMOS transistor and the p-well corresponds to a NMOS transistor.
